(19) United States
(12) Patent Application Publication
(10) Pub. No.: US 2009/0073701 A1
(43) Pub. Date: Mar. 19, 2009

(54) ELECTRICAL CONNECTING APPARATUS

(75) Inventor: Cheng Wei LO, Keelung (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Lotes Co., LTD., Keelung (TW)

(21) Appl. No.: 12/142,909

(22) Filed: Jun. 20, 2008

(30) Foreign Application Priority Data
Sep. 13, 2007 (CN) 200710030212.4

(51) Int. Cl. F21V 29/00; H05K 1/00

(52) U.S. Cl. 362/373; 439/56

(57) ABSTRACT

An electrical connecting apparatus, disclosed for a LED module, comprises a circuit board and an electrical connector disposed on the circuit board. The electrical connector comprises at least one insulator for accommodating the LED module, at least one heat-conducting device for conducting thermal energy generated by the LED module, and at least two terminals respectively contacting the LED module and the circuit board. The electrical connector can connect the LED module and the circuit board. However, only the LED module has to be replaced when it is broken. The LED can be replaced easily and the cost can be reduced. Furthermore, the LED module will not emit light onto the heat-conducting device disposed on the electrical connector. Moreover, the thermal energy generated by the LED module can be quickly conducted to the circuit board by the heat-conducting device and then be dissipated by heat sinks of a heat-dissipating module.

### BACKGROUND OF THE INVENTION

1. Field of the invention

The invention relates to an electrical connecting apparatus and, more particularly, to an electrical connecting apparatus electrically connected to a LED module.

2. Description of the prior art

The light emitting diode (LED) is a light-emitting component which is composed of semiconductor materials and utilizes combination between electrons and electron holes in a semiconductor chip to emit photons and furthermore emit lights in different frequencies.

FIG. 1 shows a common low-power LED module 10. Because the power of the LED module is low, it can only be applied to an indicator light, a button, a backlight source of a LCD screen, a guiding light of a switch, an outdoor display, a symbol displaying light, a replaceable white light bulb, and so on. The working current of each one is generally between 5 mA˜30 mA, 20 mA in typical, and each one is welded on a FR4 printed circuit board (epoxy plate) 20. The LED module 10 comprises an epoxy dome lens 12 for packaging a chip 11 and two electrical conducting regions (lead frame) 13 and 14 extended from the epoxy dome lens 12, wherein light emitted from the chip 11 passes through the epoxy dome lens 12 and sends out. One of the lead frames 13 and 14 is a positive lead frame, and the other is a negative lead frame. Each of them has a long terminal, which is welded on the FR4 printed circuit board 20 via solder 30. Cost of the LED module 10 is low and the LED module 10 is not easy to be broken in common situation. Because of the low cost, the LED module can be replaced together with the circuit board when it is broken.

High-power LED module is mainly used for a backlight source of a LCD screen, a lighting apparatus of a car, a blazing flashlight, an advertisement signboard, a photoflash of a mobile phone, a lighting module or a general illuminant, and so on. The working current of each LED is between 330 mA˜1 A and the power consumption of each increases over 10 times, even several 10 times. Therefore, the thermal energy generated by the high-power LED is 10 times more than that of the low-power LED, however, lighting power is decreased as temperature increases. Influence of temperature is linear with brightness, but exponential with operating life. Take temperature of contacting surface for instance, the operating life will be about 20,000 hours if LED is used below 50° C., only 10,000 hours when used at 75° C., 5,000 hours at 100° C., 2,000 hours at 125° C., and 1,000 hours at 150° C. The operating life is reduced to 25% from 20,000 hours to 5,000 hours as temperature increases from 50° C. to 100° C. and the LED module is severely damaged. Therefore, the demand for the development of high heat-resistant and high-sealing materials is more significant now.

FIG. 2 is a schematic diagram illustrating a LED module 10 welded on a circuit board 20 in prior art. Only one LED module is welded on a circuit board in FIG. 2, but multiple LED modules are involved in practical applications. The LED module comprises a crystal 12 for packaging a chip 11, an insulating base 13 and multiple lead frames 14 embedded in and extended out of the insulating base 13, wherein the crystal 12 is composed of a transparent plastic, glass or ceramic material. Light emitted from the chip 11 passes through the crystal 12 to illuminate on a target. The crystal 12 is accommodated in the insulating base 13 and a heatsink slug 15 is also accommodated in the insulating base 13. Multiple lead frames 14 are required to meet the demand, and they are divided into positive lead frames and negative lead frames. The multiple lead frames 14 are welded on an electrical conducting blade 21 of the circuit board 20 via solder 30 to fix the LED module 10 on the circuit board 20.

The LED module 10 conducts thermal energy generated by the LED module to the circuit board 20 via the solder 30 or a heat-conducting medium 40, and the circuit board conducts the thermal energy to the heat sink 51 of a heat-dissipating module 50, finally the thermal energy is dissipated by heat sink 51. In order to enhance heat-dissipating efficiency of the LED module 10, the FR4 printed circuit board (epoxy plate) 20 is not to be adopted. Therefore, the circuit board 20 is a printed circuit board with metal core, called MCPCB. Heat-dissipating efficiency of the MCPCB is higher than that of the traditional FR4 PCB, about 1 W/m.K˜2.2 W/m.K. Although the heat-dissipating efficiency of the MCPCB is better than that of the FR4 PCB, heat-conducting rate of the MCPCB is not so well in a dielectric layer and only 0.3 W/m.K, which is the same as FR4 PCB. Because of the characteristics of an insulating layer, there are a lot of restrictions on heat-conducting efficiency, which become a heat-conducting bottleneck between the heat-dissipating block and the metal blade.

Because a high-power LED module generates more thermal energy, accessories of the LED module are easily broken during long-term operation. Also, the LED module is directly welded on the circuit board of the MCPCB at present, the circuit board has to be replaced, too, when the LED module needs to be replaced, and thereby the cost becomes higher. Furthermore, although heat-dissipating efficiency of the circuit board of the MCPCB is higher than that of the traditional FR4 PCB, the heat-conducting rate of the circuit board of the MCPCB is not so well in dielectric layer. Therefore, a device has to be added to make it unnecessary for the LED module to be welded on the circuit board, so the LED module can be replaced or repaired easily and has good heat-dissipating efficiency via the device.

### SUMMARY OF THE INVENTION

A scope of the invention is to provide an electrical connecting apparatus for making a LED module replaced easily and dissipate thermal energy quickly.

The invention provides an electrical connecting apparatus and a LED module is disposed on the electrical connecting apparatus. The electrical connecting apparatus comprises a circuit board and at least one electrical connector disposed on the circuit board for disposing the LED module. The electrical connector comprises at least one insulator disposed on the circuit board and the LED module is disposed on the insulator, at least one heat-conducting device contacting the LED module for conducting thermal energy generated by the LED module and the heat-conducting device is located outside the light transmission range of the LED module, and at least two terminals, the two ends of each terminal electrically contacting the LED module and the circuit board respectively.

The invention provides an electrical connecting apparatus and a light-emitting module is disposed on the electrical connector. The electrical connector comprises an insulator with at least one accommodating space for accommodating the light-emitting module, at least one heat-conducting device disposed on the insulator, at least partial surface of the heat-conducting device adjoining the accommodating space, and the heat-conducting device is located outside the light transmission range of the light-emitting module, and at least two terminals respectively disposed on the insulator, and at least one end of each terminal electrically contacting the light-emitting module.

The electrical connector is to be an interface between a LED module and a circuit board for connecting the LED module to the circuit board. When the LED module is broken, only the LED module needs to be replaced and the circuit board and the heat-dissipating module do not have to be replaced, so as to save the cost and enable convenient replacement. Moreover, heat-conducting device is disposed on the electrical connector and located outside the light transmission range of the LED module, so the LED module will not emit light onto the heat-conducting device. Besides, the thermal energy generated by the LED module can be quickly conducted to the circuit board by the heat-conducting device and then be dissipated by heat sinks of a heat-dissipating module. Therefore, the thermal energy generated by the LED module does not need to be directly conducted to the circuit board to delay the LED module dissipation because of bad heat-conducting rate in dielectric layer of the circuit board.

The advantage and spirit of the invention may be understood by the following recitations together with the appended drawings.

### BRIEF DESCRIPTION OF THE APPENDED DRAWINGS

FIG. 1 is a schematic diagram illustrating a LED module welded on a circuit board in prior art.

FIG. 2 is a schematic diagram illustrating another LED module welded on a circuit board in prior art.

FIG. 3 is a schematic diagram illustrating a combination of an electrical connector and a LED module according to the first embodiment of the invention.

FIG. 4 is a perspective diagram illustrating the LED module shown in FIG. 3.

FIG. 5 is a cross-sectional diagram illustrating the LED module shown in FIG. 4.

FIG. 6 is a perspective diagram illustrating the electrical connector shown in FIG. 3.

FIG. 7 is a cross-sectional diagram illustrating the electrical connector shown in FIG. 6.

FIG. 8 is a schematic diagram illustrating a combination of an electrical connector and a LED module according to the second embodiment of the invention.

FIG. 9 is a schematic diagram illustrating a combination of an electrical connector and a LED module according to the third embodiment of the invention.

FIG. 10 is a perspective diagram illustrating an electrical connector according to the fourth embodiment of the invention.

FIG. 11 is a cross-sectional diagram illustrating an electrical connector according to the fifth embodiment of the invention.

FIG. 12 is a schematic diagram illustrating a combination of a LED module and the electrical connector shown in FIG. 1.

FIG. 13 is a cross-sectional diagram illustrating an electrical connector according to the sixth embodiment of the invention.

FIG. 14 is a schematic diagram illustrating a combination of a LED module and the electrical connector shown in FIG. 13.

FIG. 15 is a cross-sectional diagram illustrating an electrical connector according to the seventh embodiment of the invention.

FIG. 16 is a cross-sectional diagram illustrating the electrical connector with a heat-conducting medium shown in FIG. 15.

FIG. 17 is a cross-sectional diagram illustrating an electrical connector according to the eighth embodiment of the invention.

FIG. 18 is a cross-sectional diagram illustrating the electrical connector with a vacuum suction pump shown in FIG. 17.

FIG. 19 is a schematic diagram illustrating a combination of an electrical connector and a LED module according to the ninth embodiment of the invention.

FIG. 20 is a schematic diagram illustrating a combination of an electrical connector and a LED module according to the tenth embodiment of the invention.

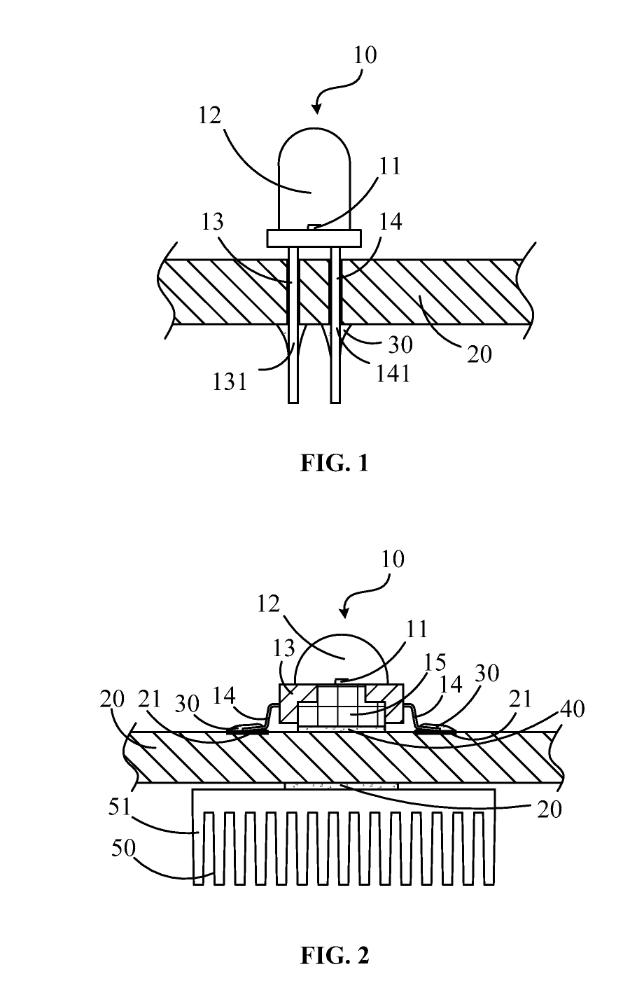

### DETAILED DESCRIPTION OF THE INVENTION

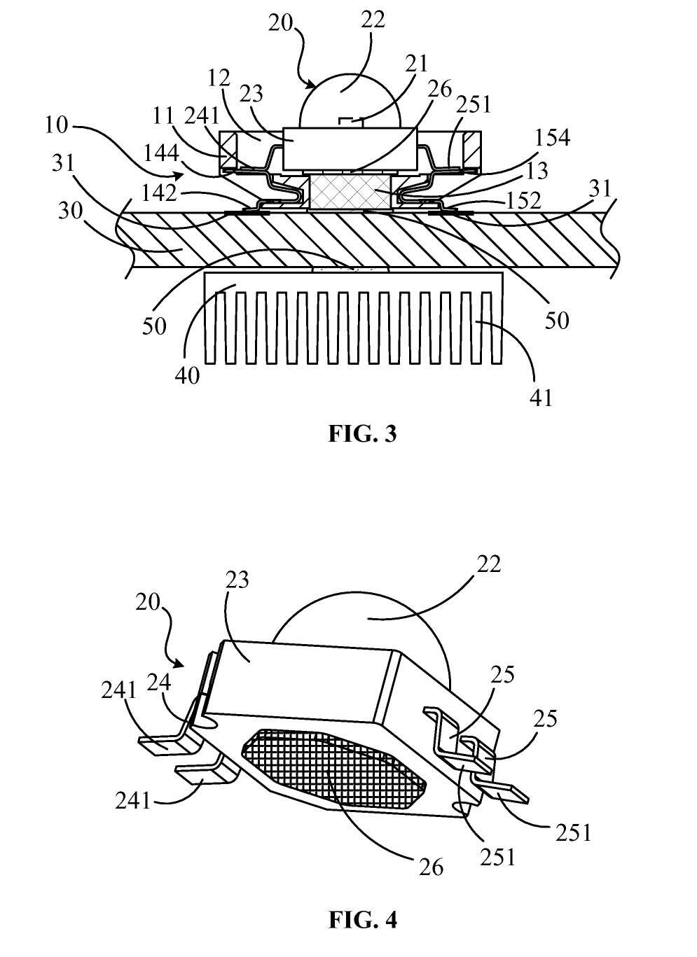

Please refer to FIG. 3 through FIG. 7. From FIG. 3 to FIG. 7 are schematic diagrams according to the first embodiment of the invention. FIG. 3 is a schematic diagram illustrating a combination of a LED module 20 and an electrical connector 10 of the invention. The electrical connecting apparatus is provided for a LED module 20 and comprises an electrical connector 10 and a circuit board 30. The electrical connector 10 is used for electrically connecting the LED module 20 to the circuit board 30, and the circuit board 30 is a MCPCB with good thermal conductivity for dissipating thermal energy generated by the LED module 20 through a heat-dissipating module 40.

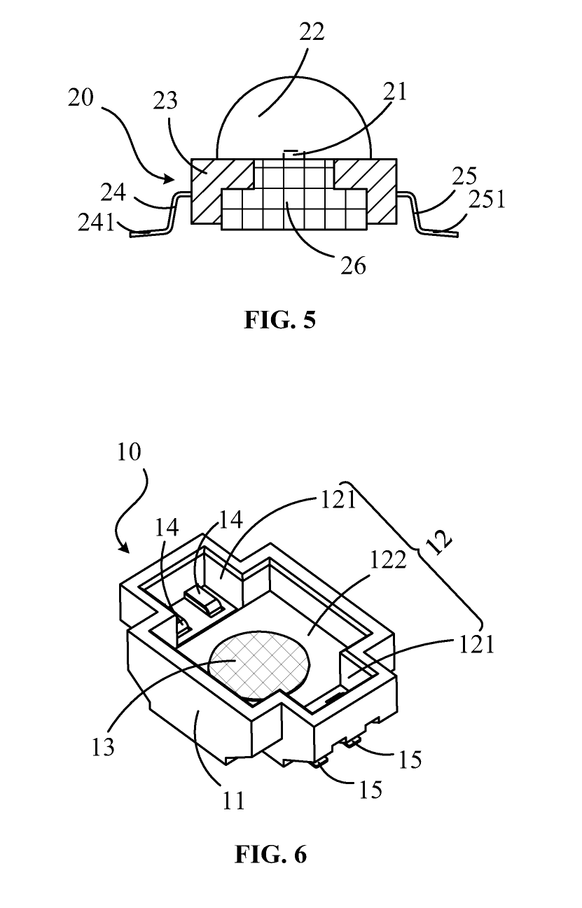

Please refer to FIG. 4 and FIG. 5. FIG. 4 and FIG. 5 show a common high-power LED module 20 which comprises a crystal 22 for packaging a light-emitting component 21, an insulating base 23, two first lead frames 24, two second lead frames 25 embedded in and extended out the insulating base 23 and a heat-conducting block 26.

The crystal 22 is composed of a transparent plastic, glass or ceramic material. Light emitted from the light-emitting component 21 passes through the crystal 22 to illuminate on a target. The crystal 22 is accommodated in the insulating base 23, and the insulating base 23 is a rectangle in general (the insulating base can also be designed in the shape of a LED module. It is a rectangle in this embodiment, but it can also be a hexagon or other shapes).

The heat-conducting block 26 is accommodated in the insulating base 23. A top end of the heat-conducting block 26 contacts the light-emitting component 21, and a bottom end of the heat-conducting block 26 extends out of the insulating base 23 to conduct thermal energy generated by the light-emitting component 21 to other objects through the heat-conducting block 26.

The two first lead frames 24 and the two second lead frames 25 are respectively divided into positive lead frames and negative lead frames. Each of the first lead frames 24 has a first contacting leg 241, and each of the two second lead frames 25 has a second contacting leg 251.

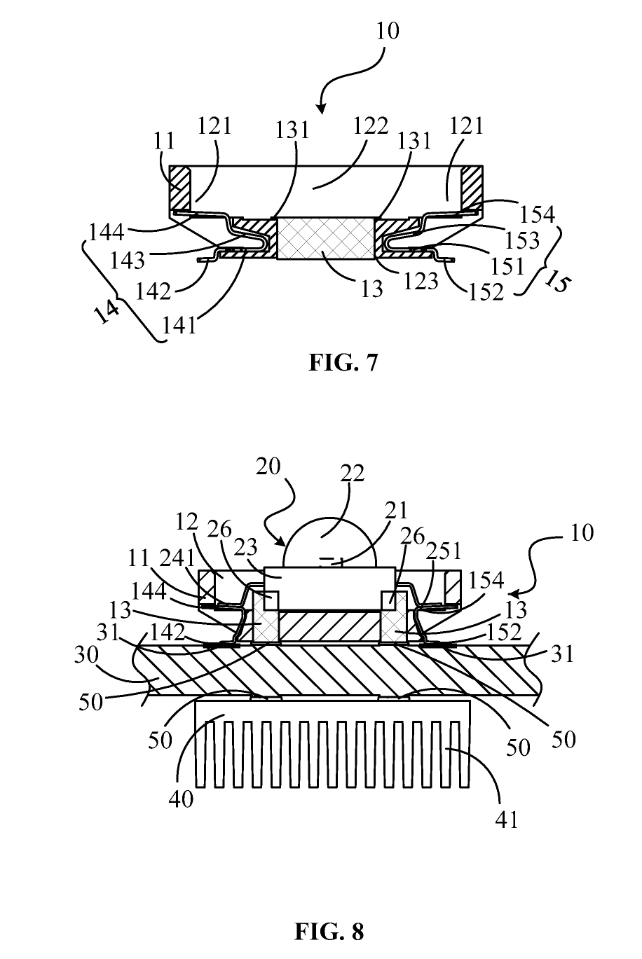

Please refer to FIG. 6 and FIG. 7. FIG. 6 and FIG. 7 are schematic diagrams illustrating an electrical connector 10 of the invention. The electrical connector 10 comprises an insulator 11, two first terminals 14, two second terminals 15 and at least one heat-conducting device 13.

An accommodating space 12 is formed around the insulator 11 for accommodating the LED module 20. The accommodating space 12 is composed of two first accommodating spaces 121 located at two ends of the insulator 11 and a second accommodating space 122 located at the middle of the two first accommodating spaces 121. The two first accommodating spaces 121 are opposite to each other, and the first accommodating spaces 121 adjoin the two second accommodating space 122. Furthermore, the middle of the two second accommodating space 122 has a through channel 123 penetrating the insulator 11.

The heat-conducting device 13 is manufactured from metal materials for conducting thermal energy generated by the light-emitting component 21 of the LED module 20. The heat-conducting device 13 is accommodated in the through channel 123 of the accommodating space 12, the heat-conducting device 13 extends out of the bottom surface of the insulator 11, and partial surface of the heat-conducting device 13 adjoins outer surface of the insulator 11. The heat-conducting device 13 exposes partial surface for contacting with other component and a block 131 extends from each of the two extremities of the heat-conducting device 13, respectively. The blocks 131 are jammed in the two sides of the through channel 123 to prevent the heat-conducting device 13 from sliding out of the through channel 123.

As shown in FIG. 3, the heat-conducting device 13 is located outside the light transmission range of the light-emitting component 21 of the LED module 20 and thermal energy generated by LED module is conducted between the heat-conducting device 13 and the heat-conducting block 26 of the LED module 20 to be conducted out through the heat-conducting device 13.

The first terminal 14 and the second terminal 15 are accommodated in the accommodating space 12 and respectively accommodated in the two first accommodating spaces 121 which are opposite to each other, and furthermore, the first terminal 14 and the second terminal 15 are located at the two sides of the heat-conducting device 13.

The first and second terminals 14 and 15 comprise a first and second bases 141 and 151 disposed in the insulator 11 respectively, a first and second welding portions 142 and 152 extend from the two extremities of the first and second bases 141 and 151, and a first and second elastic beams 143 and 153. The first and second elastic beams 143 and 153 still extend upward to form a first and second contacting portions 144 and 154, respectively.

As shown in FIG. 3, the first and second welding portions 142 and 152 electrically contact an electrical conducting plate 31 of the circuit board 30 and are welded on the electrical conducting plate 31 of the circuit board 30, respectively, for fixing the electrical connector 10 on the circuit board 30. The first and second contacting portions 144 and 154 also electrically contact the first and second contacting legs 241 and 251 of the LED module 20, respectively, for achieving electrical connection between the LED module 20 and the circuit board 30.

Please refer to FIG. 3 through FIG. 7. During fabrication, first of all, the heat-dissipating module 40 is fixed on a side of the circuit board 30 and a heat-conducting medium 50 with a certain thickness is disposed between the heat-dissipating module 40 and the circuit board 30 for filling clearance between the heat-dissipating module 40 and the circuit board 30 and reducing thermal resistance between the heat-dissipating module 40 and the circuit board 30.

Secondly, the electrical connector 10 is welded on the circuit board 30 and the first and second welding portions 142 and 152 of the first and second terminals 14 and 15 of the electrical connector 10 are welded on the corresponding electrical conducting plates 31 of the circuit board 30. Besides, the heat-conducting device 13 of the electrical connector 10 is disposed on an upper surface of the circuit board 30, and the heat-conducting device 13 of the circuit board 30 is opposite to the heat-dissipating module 40. Furthermore, heat-conducting medium 50 with a certain thickness is disposed between the heat-conducting device 13 and the circuit board 30 for reducing thermal resistance between the heat-conducting device 13 and the circuit board 30 and fixing the electrical connector 10 on the circuit board 30 to achieve electrically conducting between the electrical connector 10 and the circuit board 30.

Finally, the LED module 20 is disposed in the electrical connector 10. The insulating base 23 of the LED module 20 is accommodated in the accommodating space 12 of the electrical connector 10, and makes the heat-conducting block 26 of the LED module 20 just opposite to the heat-conducting device 13 of the electrical connector 10 for conducting thermal energy generated by LED module 20 to the heat-dissipating module 40 through the heat-conducting device 13 of the electrical connector 10. Afterward, the first and second contacting legs 241 and 251 of the first and second lead frames 24 and 25 of the LED module 20 are disposed respectively on the first and second contacting portions 144 and 154 of the first and second terminals 14 and 15 of the electrical connector 10 for achieving electrically conducting between the LED module 20 and the electrical connector 10.

Because the electrical connector 10 has been welded on the circuit board 30, there is electrical conduction between the LED module 20 and the circuit board 30 through the electrical connector 10. The electrical connector 10 has a heat-conducting device 13, and there is heat conduction between the heat-conducting device 13 and the heat-conducting block 26 of the LED module. The heat-conducting device 13 is located outside the light transmission range of the light-emitting module 21 of the LED module 20, so the LED module 20 will not emit light onto the heat-conducting device 13, and thermal energy generated by the LED module 20 can be quickly conducted to the heat-conducting device 13 and then to heat-dissipating module 40 through the circuit board 30. Finally, thermal energy can be dissipated by the heat-dissipating module 40, and thermal energy generated by the LED module 20 can not be directly conducted to the circuit board 30 to delay the LED module heat-dissipating because of bad heat-conducting rate in dielectric layer of the circuit board.

The electrical connector of the invention is used as a medium between the LED module and the circuit board for connecting the LED module to the circuit board. When the LED module is broken, only the LED module needs to be replaced and it is not necessary to replace the circuit board and the heat-dissipating module together, so as to reduce cost and enhances convenient replacement. Moreover, at least one heat-conducting device is disposed on the electrical connector and located outside the light transmission range of the LED module, so the LED module does not emit light onto the heat-conducting device, and the thermal energy generated by the LED module can be quickly conducted to the circuit board by the heat-conducting device and then be dissipated by a heat sinks of a heat-dissipating module. Therefore, the thermal energy generated by the LED module will not be directly conducted to the circuit board so as to avoid the delay of the LED module heat-dissipating because of bad heat-conducting rate in dielectric layer of the circuit board.

FIG. 8 is a schematic diagram illustrating a combination of an electrical connector and a LED module according to the second embodiment of the invention. The difference between this embodiment and the aforesaid embodiment is that at least four heat-conducting blocks 26 are disposed in the insulating base 23 of the LED module 20 and located at the two ends and sides of the insulating base 23. The heat-conducting blocks 26 can be designed in the shape of a barrel or a ring, and so on, and surround at any position of the insulating base 23. Furthermore, at least four heat-conducting devices 13 correspond respectively to the four heat-conducting blocks 26 of the LED module 20. When the heat-conducting blocks 26 are designed in the shape of a barrel, a ring or anything similar and surround at any position of the insulating base 23, the heat-conducting devices 13 are also designed in the shape of a barrel, a ring or anything similar and surround at any position of the insulating base 23, corresponding to the heat-conducting blocks 26. Certainly, in other embodiments, there are multiple heat-conducting devices 13 and each heat-conducting device 13 corresponds to at least one heat-conducting block 26 of the LED module 20, or there are multiple heat-conducting blocks 26 and each heat-conducting block 26 corresponds to at least one heat-conducting device 13.

The heat-dissipating module 40 corresponding to each heat-conducting device 13 are disposed under the circuit board 30, and there is a heat-conducting medium 50 between each heat-dissipating module 40 and the circuit board 30. Similarly, there is a heat-conducting medium 50 between each heat-conducting device 13 and the circuit board 30. Therefore, thermal energy generated by the LED module 20 can be conducted to the heat-conducting device 13 of the electrical connector 10 from the heat-conducting block 26 in multiple directions and then to the heat-dissipating module 40. Finally thermal energy is dissipated by heat sinks 41 of the heat-dissipating module 40, and thereby area of the heat-conducting block 26 of the LED module 20 is increased for enhancing heat-dissipation efficiency. Other structures of the embodiment are the same as the aforesaid first embodiment and will not be mentioned again here.

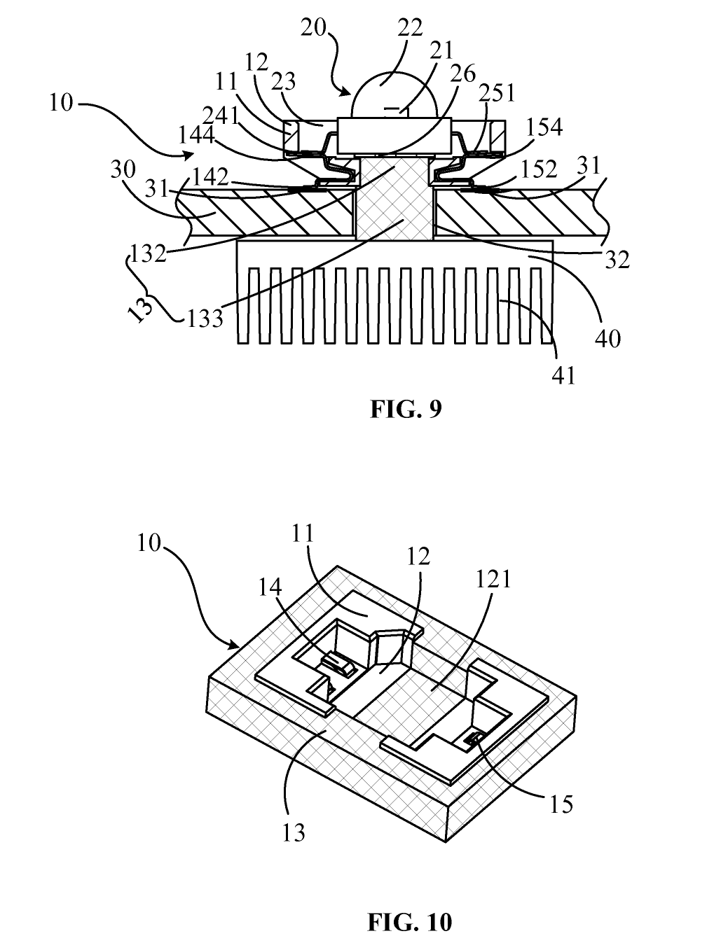

FIG. 9 is a schematic diagram illustrating a combination of an electrical connector and a LED module according to the third embodiment of the invention. The difference between this embodiment and the aforesaid first embodiment is that the heat-conducting device 13 of the electrical connector 10 is composed of a first heat-conducting device 131 disposed in the insulator 11 and a second heat-conducting device 132 extends from the first heat-conducting device 131. The second heat-conducting device 132 is accommodated in a penetrating hole 32 of the circuit board 30 and penetrates the penetrating hole 32. Partial of the second heat-conducting device 123 exposing at the bottom surface of the circuit board 30 directly contacts the heat-dissipating module 40 under the circuit board 30, and the heat-conducting device 13 extends through the circuit board 30 to directly form a heat conduction with the heat-dissipating module 40. Thermal energy generated by the LED module 20 can be directly conducted to the heat-dissipating module 40 through the heat-conducting device 10 in this heat-dissipating mode and then be dissipated by the heat-dissipating module. The heat-dissipating mode is more convenient and quicker, and it is not necessary to conduct thermal energy to the circuit board 30. It not only avoids delaying the LED module heat-dissipating because of bad heat-conducting rate in dielectric layer of the circuit board, but also saves on cost. Other structures of the embodiment are the same as the aforesaid first embodiment and will not be mentioned again here.

FIG. 10 is a schematic diagram illustrating an electrical connector according to the fourth embodiment of the invention. The difference between this embodiment and the aforesaid embodiment is that the heat-conducting device 13 is not only disposed outside the accommodating space 12 of the electrical connector 10 but also covers at least partial surface of the insulator 11 of the electrical connector 10, and in FIG. 10 the heat-conducting device 13 covers the entire surface of the insulator 11 to make the whole lower surface of insulator 11 contact the circuit board 30 to have a larger area for heat-dissipating more convenient and quicker. Other structures of the embodiment are the same as the aforesaid third embodiment and will not be mentioned again here.

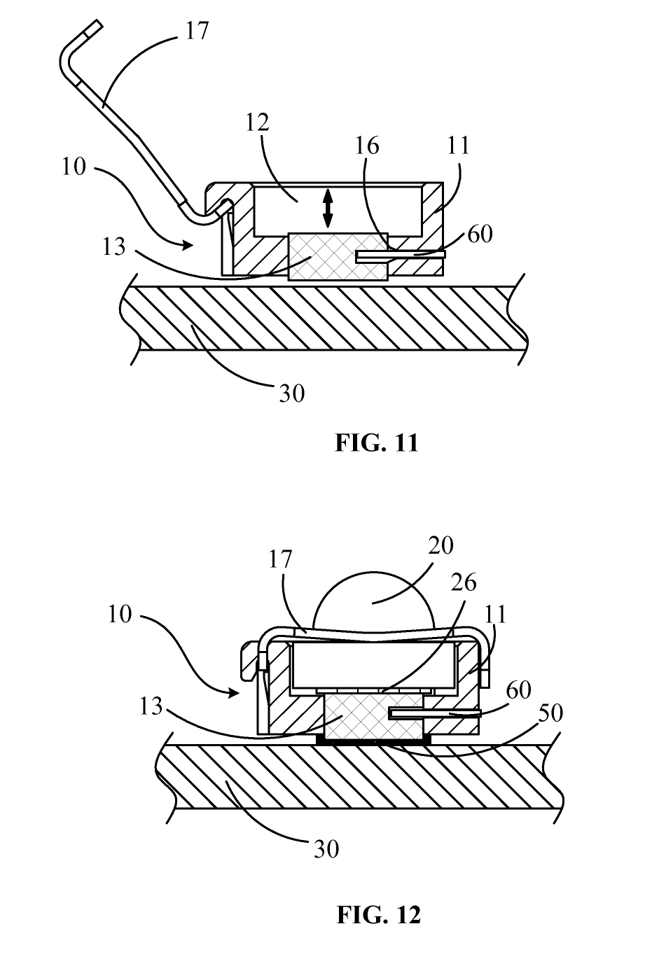

FIG. 11 and FIG. 12 are schematic diagrams illustrating a combination of a LED module and an electrical connector according to the fifth embodiment of the invention. Differences between this embodiment and the aforesaid first embodiment are that the electrical connector 10 has a groove 16 located at the insulator 11 and the heat-conducting device 13, and a restricting structure 60 is disposed in the groove 16. The restricting structure 60 is an elastic piece and one part is located in the heat-conducting device 13 and the other part is located in the insulator 11, and furthermore, the restricting structure 60 is composed of an elastic metal or plastic material. In this embodiment, the restricting structure 60 is not used for heat-conduction or electrical conduction and makes the heat-conducting device 13 move upward and downward with respect to the LED module 20 and further makes the LED module 20 closely contact the heat-conducting block 26.

A suppressing component 17 is still disposed in the electrical connector 10, and an end of the suppressing component 17 is buckled on an end of the insulator 11 to fix the LED module 20 tightly in the accommodating space 12 of the electrical connector 10.

Before the LED module 20 is disposed on the electrical connector 10, there is a certain gap between the heat-conducting device 13 of the electrical connector 10 and the circuit board 30. After the LED module 20 is disposed in the accommodating space 12 of the electrical connector 10, the other end of the suppressing component 17 is buckled on the other side of the insulator 11 to fix the LED module 20 tightly in the accommodating space 12 of the electrical connector 10. In the process of buckling the suppressing component 17 on the other end of the insulator 11, the heat-conducting device 13 of the electrical connector 10 is slowly disposed on the circuit board 30. Furthermore, the restricting structure 60 makes the heat-conducting device 13 move upward and downward with respect to the LED module 20 and further makes the LED module 20 closely contact the heat-conducting block 26, so as to fix the electrical connector 10 tightly with the LED module 20. Other structures of the embodiment are the same as the aforesaid third embodiment and will not be mentioned again here.

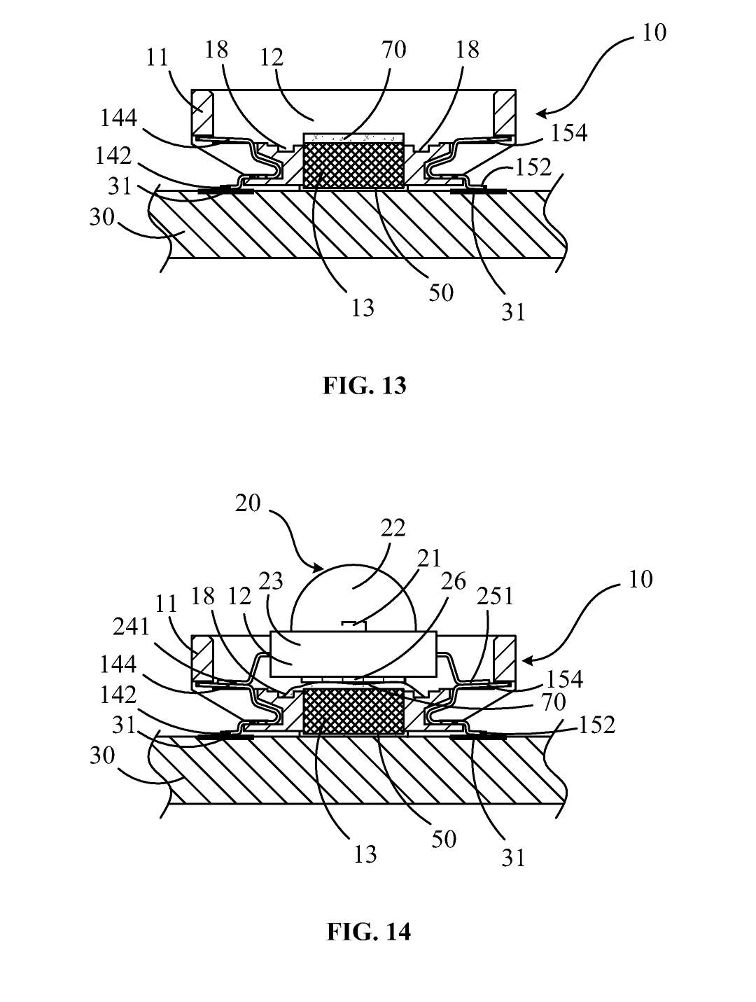

FIG. 13 and FIG. 14 are schematic diagrams illustrating a combination of a LED module and an electrical connector according to the sixth embodiment of the invention. Differences between this embodiment and the aforesaid first embodiment are that a heat-conducting medium 70 is disposed on a contacting surface between the heat-conducting device 13 of the electrical connector 10 and the LED module 20. The heat-conducting medium 70 makes the heat-conducting device 13 contact the heat-conducting block 26 of the LED module 20 and quickly conducting thermal energy generated by the LED module 20 to the heat-dissipating module 40 through the heat-conducting device 10. The electrical connector 10 also has multiple overflow grooves 18 in the accommodating space 12, and the multiple overflow grooves 18 is located around the heat-conducting medium 70. When the LED module 20 is closely contacted to the electrical connector 10, the heat-conducting block 26 of the LED module 20 will compress the heat-conducting medium 70 of the electrical connector 1O. Moreover, because partial heat-conducting medium 70 has metal granules, the heat-conducting medium 70 will be laterally extended and become deformed after the heat-conducting medium 70 be compressed by the heat-conducting block 26, and the redundant heat-conducting medium 70 will be compressed to overflow into the overflow groove 18. The overflow groove 18 can prevent the heat-conducting medium 70 from overflowing into other place in the accommodating space 12 because of the compression and even attaching on the first and the second terminal 14 and 15 of the electrical connector 10 or the first and second lead frames 24 and 25 of the LED module 20. The heat-conducting medium 70 affects electrical conduction between the first and the second terminal 14 and 15 and the first and second lead frames 24 and 25, and then affecting the electrical conduction between the electrical connector 10 and the LED module 20. Other structures of the embodiment are the same as the aforesaid first embodiment, so it will not be mentioned again here.

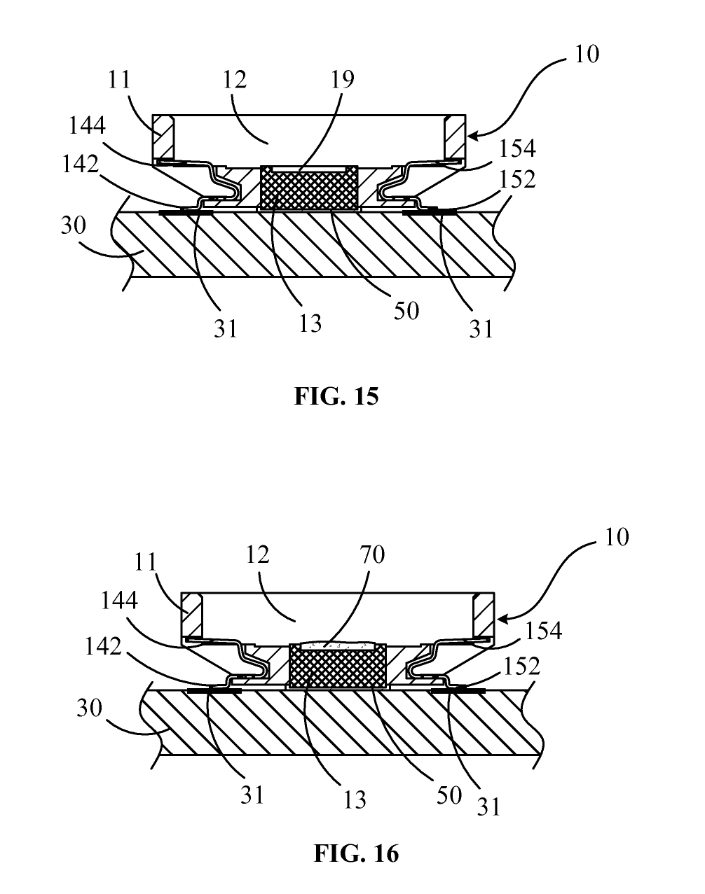

FIG. 15 and FIG. 16 are schematic diagrams illustrating an electrical connector according to the seventh embodiment of the invention. Differences between this embodiment and the aforesaid sixth embodiment are that no overflow groove is formed in the accommodating space 12 of the electrical connector 10 and a containing groove 19 is formed on an upper side of the heat-conducting device 13 of the electrical connector 10. The heat-conducting medium 70 is directly accommodated in the containing groove 19 to prevent the heat-conducting medium 70 from overflowing outward because the LED module 20 is compressed. Other structures of the embodiment are the same as the aforesaid sixth embodiment, so it will not be mentioned again here.

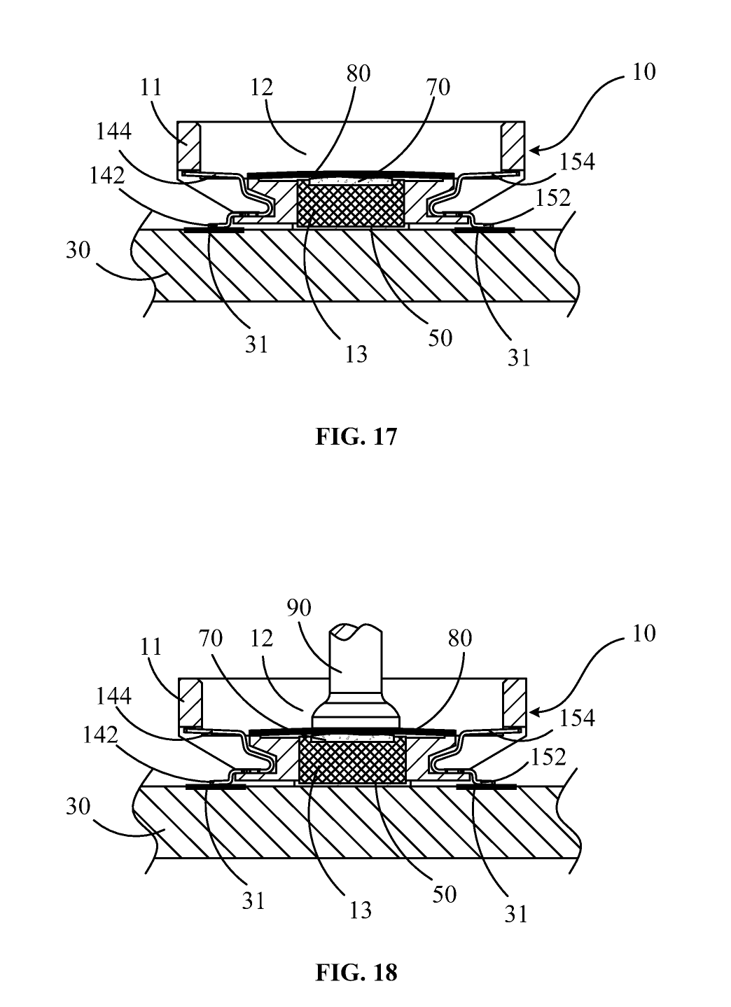

FIG. 17 and FIG. 18 are schematic diagrams illustrating an electrical connector according to the eighth embodiment of the invention. Differences between this embodiment and the aforesaid seventh embodiment are that a film 80 is disposed on the heat-conducting medium 70 of the electrical connector 10. The film 80 can prevent the heat-conducting medium 70 from spoiling and can still be an action of vacuum suction. Furthermore, the film 80 is sucked through a vacuum suction pump 90 to dispose the electrical connector 10 on a predetermined welding position on the circuit board 30. Other structures of the embodiment are the same as the aforesaid seventh embodiment and will not be mentioned again here.

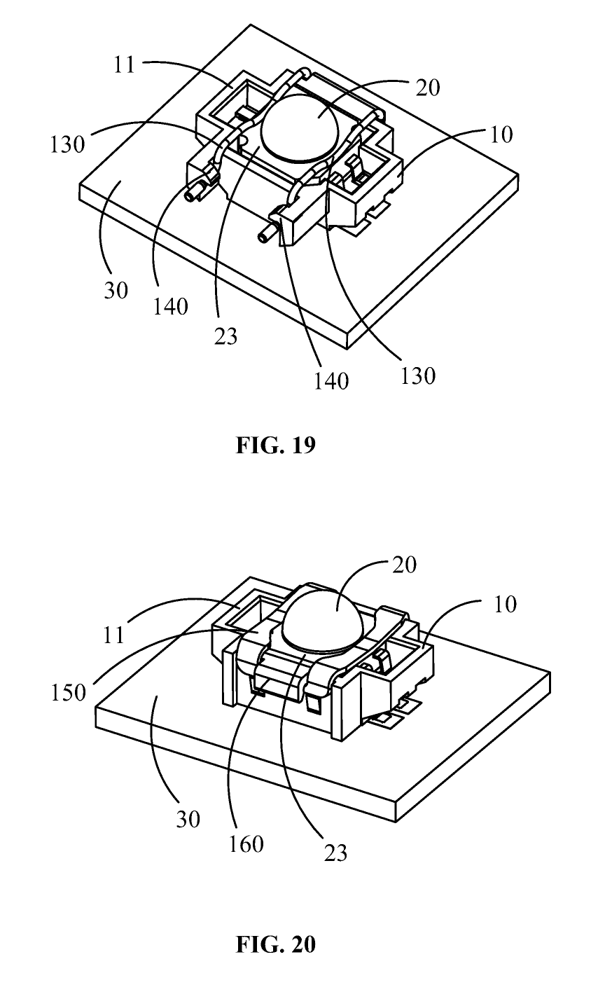

FIG. 19 is a schematic diagram illustrating a combination of an electrical connector and a LED module according to the ninth embodiment of the invention. Differences between this embodiment and the aforesaid first embodiment are that two buttons 130 are disposed on the electrical connector 10 and the buttons 130 are also accommodating spaces in practical. The buttons 130 are disposed on the insulating base 23 of the LED module 20 and buckled in a buckling groove 140 of the electrical connector 10 for fixing the LED module 20 in the electrical connector 10, and the LED module 20 can be easily replaced by utilizing the buttons 130. Furthermore, well electrical conduction efficiency and heat conduction efficiency between the LED module 20 and the electrical connector 10 can be maintained after the LED module 20 is replaced. Other structures of the embodiment are the same as the aforesaid first embodiment and will not be mentioned again here.

FIG. 20 is a schematic diagram illustrating a combination of an electrical connector and a LED module according to the tenth embodiment of the invention. Differences between this embodiment and the aforesaid ninth embodiment are that an upper cover 150 is disposed on the electrical connector 10, and the upper cover 150 is also accommodating space in practical. The upper cover 150 is buckled on the insulating base 23 of the LED module 20 and buckled on a buckling portion 160 of the LED module 20 for closely fixing the LED module 20 in the electrical connector 10. Other structures of the embodiment are the same as the aforesaid ninth embodiment and hence will not be mentioned again here.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An electrical connecting apparatus, a LED module being disposed on the electrical connecting apparatus, the electrical connecting apparatus comprising:
a circuit board;
at least one electrical connector, disposed on the circuit board, for connecting the LED module, the electrical connector comprising:
at least one insulator disposed on the circuit board, the LED module being disposed on the insulator;
at least one heat-conducting device contacting the LED module and being used for conducting thermal energy generated by the LED module, the heat-conducting device being located outside a light transmission range of the LED module; and
at least two terminals, both ends of each terminal electrically contacting the LED module and the circuit board.

2. The electrical connecting apparatus of claim 1, wherein the electrical connector further comprises at least one fixing device for fixing the LED module.

3. The electrical connecting apparatus of claim 1, wherein each of the terminals has a base disposed in the insulator, a welding portion and a contacting portion extending from the base.

4. The electrical connecting apparatus of claim 3, wherein the LED module has an electrical conducting region for contacting the contacting portion of each terminal.

5. The electrical connecting apparatus of claim 3, wherein the circuit board has an electrical conducting plate for contacting the welding portion of each terminal.

6. The electrical connecting apparatus of claim 1, wherein the LED module comprises an insulating base, at least one heat-conducting block accommodated in the insulating base and a light-emitting component contacting the heat-conducting block, and heat is conducted between the heat-conducting device and the heat-conducting block.

7. The electrical connecting apparatus of claim 6, wherein there are several heat-conducting devices and each heat-conducting device corresponds to at least one heat-conducting block of the LED module.

8. The electrical connecting apparatus of claim 6, wherein there are several heat-conducting blocks and each heat-conducting block corresponds to at least one heat-conducting device.

9. The electrical connecting apparatus of claim 1, wherein the heat-conducting device is deposed on the circuit board, and there is a heat-conducting medium between the heat-conducting device and the circuit board.

10. The electrical connecting apparatus of claim 1, wherein a heat-dissipating module is located at one side of the circuit board, and there is a heat-conducting medium between the heat-dissipating module and the circuit board.

11. The electrical connecting apparatus of claim 1, wherein a heat-dissipating module is located at one side of the circuit board, and the heat-conducting device extends through the circuit board and conducts heat with the heat-dissipating module.

12. The electrical connecting apparatus of claim 1, wherein the insulator has a through channel for accommodating the heat-conducting device.

13. The electrical connecting apparatus of claim 1, wherein the heat-conducting device covers at least one part of the insulator.

14. The electrical connecting apparatus of claim 1, wherein a restricting structure is deposed in the electrical connector.

15. The electrical connecting apparatus of claim 14, wherein one part of the restricting structure is located in the heat-conducting device and the other part is located in the insulator.

16. The electrical connecting apparatus of claim 1, wherein there is a heat-conducting medium between the heat-conducting device and the LED module.

17. The electrical connecting apparatus of claim 16, wherein at least one overflow groove is formed in the electrical connector, and the overflow groove is located around the heat-conducting medium.

18. The electrical connecting apparatus of claim 1, wherein a containing groove is formed on a surface of the heat-conducting device.

19. The electrical connecting apparatus of claim 18, wherein there is a heat-conducting medium in the containing groove.

20. The electrical connecting apparatus of claim 19, wherein a film is disposed on the heat-conducting medium.

21. An electrical connector, a light-emitting module being disposed on the electrical connector, the electrical connector comprising:
an insulator having at least one accommodating space for accommodating the light-emitting module;
at least one heat-conducting device disposed on the insulator, at least partial surface of the heat-conducting device adjoining the accommodating space, and the heat-conducting device being located outside a light transmission range of the light-emitting module; and
at least two terminals respectively disposed on the insulator, and at least one end of each terminal electrically contacting the light-emitting module
